(19) United States
(12) Patent Application Publication
(10) Pub. No.: US 2010/0006148 A1
(43) Pub. Date: Jan. 14, 2010

(54) SOLAR CELL WITH POROUS INSULATING LAYER

(75) Inventors: Zhi Zheng, Shanghai (CN); Tao Pan, Shanghai (CN); Linan Zhao, Shanghai (CN); Wei Jun Wang, Shanghai (CN); Xuanbin Liu, Shanghai (CN)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: HONEYWELL INTERNATIONAL INC., Morristown, NJ (US)

(21) Appl. No.: 12/497,406

(22) Filed: Jul. 2, 2009

Related U.S. Application Data
(60) Provisional application No. 61/078,973, filed on Jul. 8, 2008.

(51) Int. Cl. H01L 31/0352; H01L 31/18

(52) U.S. Cl. 136/256; 438/73; 257/E21.09; 257/E31.033

(57) ABSTRACT

Disclosed are solar cells and methods for making solar cells. An example solar cell may include an electron conductor layer. The solar cell may also include a hole conductor layer. An insulating layer may be disposed between the electron conductor layer and the hole conductor layer. The insulating layer may have a plurality of pores. Absorber material may be disposed at least partially within at least some of the plurality of pores.

### PRIORITY

This application claims priority under 35 U.S.C. §119 to U.S. Provisional Application Ser. No. 61/078,973 entitled “SOLAR CELL WITH POROUS INSULATING LAYER” filed Jul. 8, 2008, the entirety of which is incorporated herein by reference.

### TECHNICAL FIELD

The disclosure generally relates to insulating layers, and more particularly to porous insulating layers for use in electronic devices such as solar cells.

### BACKGROUND

Interfacial charge recombination and other effects can reduce the efficiency of many electronic devices such as solar cells, Field Effect Transistors (FETs) and other electronic devices. In a solar cell, absorbers such as dye or Quantum Dots (QD) are often used to absorb light and generate electron-hole pairs. At least some of the generated electrons are injected into an Electron Conductor (EC), and at least some of the holes are injected into a Hole Conductor (HC), thereby creating a light induced current at the back electrode and counter electrode that contact the EC and the HC, respectively, of the solar cell. The injection efficiency of the solar cell may be defined as the percentage of electrons generated by the absorbers, dye or Quantum Dots (QD) that are actually injected to the Electron Conductor (EC) of the solar cell, and the collection efficiency may be defined as the percentage of injected electrons that are actually transported to the corresponding back electrode of the solar cell without recombining with holes.

The energy conversion efficiency of such a solar cell is related to the injection efficiency and collection efficiency. If the Electron Conductor (EC) and Hole Conductor (HC) are physically close to each other and/or not well electrically insulated, significant interfacial electron-hole recombination can occur, which can reduce the collection efficiency and thus the overall energy conversion efficiency of the solar cell. Similar interfacial charge recombination may occur in other electronic devices, such as at or near the gate oxide of a Field Effect Transistor (FETs). What may be desirable, therefore, is an insulating layer that helps reduce interfacial charge recombination and/or other effects to help improve the efficiency of such electronic devices.

### SUMMARY

This disclosure relates to generally to insulating layers, and more particularly to porous insulating layers for use in electronic devices such as solar cells and FETs. A solar cell is used as a particular example of such an electronic device in the discussion below. However, it should be understood that the application of a porous insulating layer in other electronic devices, such as FETs (Field Effect Transistors), LEDs (Light Emitting Diodes), VCSELs (Vertical Cavity Surface Emitting Lasers), RCPDs (Resonant Cavity Photo Detectors) and other devices, is also contemplated.

Some solar cells may be sensitized to improve their absorbance of incident photons. Solar cells may, for example, be sensitized with dye molecules and/or quantum dots that eject electrons upon photoexcitation. As indicated above, a solar cell may include an electron conductor and a hole conductor. In some instances, it may be useful to prevent direct contact between the electron conductor and the hole conductor in order to reduce or eliminate recombination of electrons and holes at the interface.

An example solar cell may include an electron conductor layer, a hole conductor layer, and an insulating layer disposed between the electron conductor layer and the hole conductor layer. The insulating layer may have a plurality of pores or the like. Absorber material may be disposed at least partially within at least some of the plurality of pores.

Another example solar cell may include an electron conductor layer that includes sinterized titanium dioxide. An insulating layer may be disposed over the electron conductor layer. The insulating layer may have a plurality of pores formed therein. The solar cell may also include a plurality of quantum dots. At least some of the plurality of quantum dots may be disposed at least partially within at least some of the plurality of pores of the insulating layer. A hole conductor layer may be disposed over the insulating layer and the plurality of quantum dots. The hole conductor layer may include a conductive polymer, but this is not required.

An example method of forming a solar cell may include providing an electron conductor layer, providing an insulating layer over the electron conductor layer, processing the insulating layer to include pores configured to accommodate absorber material, providing the absorber material at least partially within the pores in the insulating layer, and disposing a hole conductor layer over the absorber materials and the insulating layer.

The above summary is not intended to describe each and every disclosed embodiment or every implementation of the disclosure. The Description that follows more particularly exemplify the various illustrative embodiments.

### BRIEF DESCRIPTION OF THE FIGURES

The following description should be read with reference to the drawings. The drawings, which are not necessarily to scale, depict selected embodiments and are not intended to limit the scope of the disclosure. The disclosure may be more completely understood in consideration of the following detailed description of various embodiments in connection with the accompanying drawings, in which:

FIG. 1 is a schematic view of an illustrative but non-limiting example of a solar cell; and

FIG. 2 is a schematic cross-sectional view of a portion of the solar cell of FIG. 1.

While the invention is amenable to various modifications and alternative forms, specifics thereof have been shown by way of example in the drawings and will be described in detail. It should be understood, however, that the intention is not to limit the invention to the particular illustrative embodiments described. On the contrary, the intention is to cover all modifications, equivalents, and alternatives falling within the spirit and scope of the invention.

### DESCRIPTION

The following description should be read with reference to the drawings, in which like elements in different drawings are numbered in like fashion. The drawings, which are not necessarily to scale, depict selected embodiments and are not intended to limit the scope of the invention. Although examples of construction, dimensions, and materials are illustrated for the various elements, those skilled in the art will recognize that many of the examples provided have suitable alternatives that may be utilized.

This disclosure relates to generally to insulating layers, and more particularly to porous insulating layers for use in electronic devices such as solar cells and FETs. A solar cell is used as a particular example electronic device below. However, it should be understood that the application of a porous insulating layer is other electronic devices such as FETs is also contemplated. For example, such a porous insulating layer may be useful in helping to reduce interfacial charge recombination and/or other effects at or near the gate oxide of a FET.

In one illustrative embodiment, a solar cell may include one or more photo-excitable dyes that can absorb one or more photons and correspondingly eject one or more electrons. Any suitable photo-excitable dye, assuming it can absorb photons within a given wavelength range or ranges, may be used. Illustrative but non-limiting examples of suitable dyes include complexes of transition metals such as ruthenium, such as ruthenium tris(2,2′bipyridyl-4,4′dicarboxylate), and osmium. Examples also include porphyrins such as zinc tetra(4-carboxylphenyl)porphyrin, cyanides such as iron-hexacyanide complexes and phthalocyanines.

Alternatively, or in addition, a solar cell may include quantum dots that can absorb one or more photons and correspondingly eject one or more electrons. Quantum dots are very small semiconductors, having dimensions in the nanometer range. Because of their small size, quantum dots may exhibit quantum behavior that is distinct from what would otherwise be expected from a larger sample of the material. In some cases, quantum dots may be considered as being crystals composed of materials from Groups II-VI, III-V, or IV-VI materials. The quantum dots employed herein may be formed using any appropriate technique.

Examples of specific pairs of materials for forming quantum dots include but are not limited to MgO, MgS, MgSe, MgTe, CaO, CaS, CaSe, CaTe, SrO, SrS,SrSe, SrTe, BaO, BaS, BaSe, BaTe, ZnO, ZnS, ZnSe, ZnTe, CdO, CdS, CdSe, CdTe, HgO, HgS, HgSe, HgTe, Al₂O₃, Al₂S_{3,} Al₂Se_{3,} Al₂Te_{3,} Ga₂O_{3,} Ga₂S_{3,} Ga₂Se_{3,} Ga₂Te_{3,} In₂O_{3,} In₂S_{3,} In₂Se_{3,} In₂Te_{3,} SiO₂, GeO_{2,} SnO_{2,} SnS, SnSe, SnTe, PbO, PbO₂, PbS, PbSe, PbTe, AlN, AlP, AlAs, AlSb, GaN, GaP, GaAs, GaSb, InN, InP, InAs and InSb. Particular examples of suitable pairs of materials for forming quantum dots include Ag₂S, CdSe, CdTe and CdS.

In the illustrative embodiment, the solar cell may also include an electron conductor. In some cases, the electron conductor may be an n-type electron conductor, but this is not required. The electron conductor may be metallic and/or semiconducting, such as TiO₂ or ZnO. In some cases, the electron conductor may be an electrically conducting polymer such as a polymer that has been doped to be electrically conducting and/or to improve its electrical conductivity. In some instances, the electron conductor may be formed of titanium dioxide that has been sinterized.

In the illustrative embodiment, the solar cells may also include a hole conductor. A variety of hole conductors are contemplated. In some cases, for example, the electron conductor may be an n-type conductor that may be metallic or an electrically conductive polymer. When so provided, the hole conductor may be a p-type electrically conductive polymer or the like.

In some instances, any suitable p-type conductive polymer may be used, such as P3HT, or poly(3-hexyl thiophene), poly[3-(ω-mercapto hexyl)]thiophene, poly[3-(ω-mercapto undecyl)]thiophene, poly[3-(ω-mercapto dodecyl)]thiophene, MEH-PPV, or poly[2,5-dimethoxy-1,4-phenylene-1,2-ethenylene,2-methoxy-5-2-ethylhexyloxy-1,4-phenylene-1,2-ethylene), PPP, or poly(p-phenylene), TFB, or poly(9,9-dioctylfluorene-co-N-(4-(3-methylpropyl)-diphenylamine), and the like. In some instances, the hole conductor may be a p-type semiconductor. Illustrative but non-limiting examples of suitable p-type semiconductors include CuI and CuSCN. The hole conductor may be a non-polymeric organic molecule such as spiro-OMeTAD.

In some cases, the hole conductor may be an electrolyte. An illustrative but non-limiting example of an electrolyte may be formed by dissolving suitable redox materials such as combinations of metal iodides with iodine or combinations of metal bromides with bromine. Examples of suitable metal iodides include LiI, NaI, KI, CaI₂ and MgI₂. Examples of suitable metal bromides include LiBr, NaBr, KBr and CaBr₂. Examples of suitable solvents include but are not limited to carbonate compounds and nitrile compounds. In some instances, the hole conductor may be an ionic liquid such as 1-methyl-3-ethylimidazolium dicyanamide (EMIDCN), 1-propyl-3-methylimidazolium iodide(PMII), 1-ethyl-3-methylimidazolium thiocyanate (EMISCN), and the like. The ionic liquid may include an electrolyte such as LiI, iodine or NMBI.

In some instances, the hole conductor may be an electrolyte gel that includes an ionic liquid and an electrolyte as discussed above, but may also include a gelling agent or gelator. Illustrative but non-limiting examples of suitable gelators are shown below:

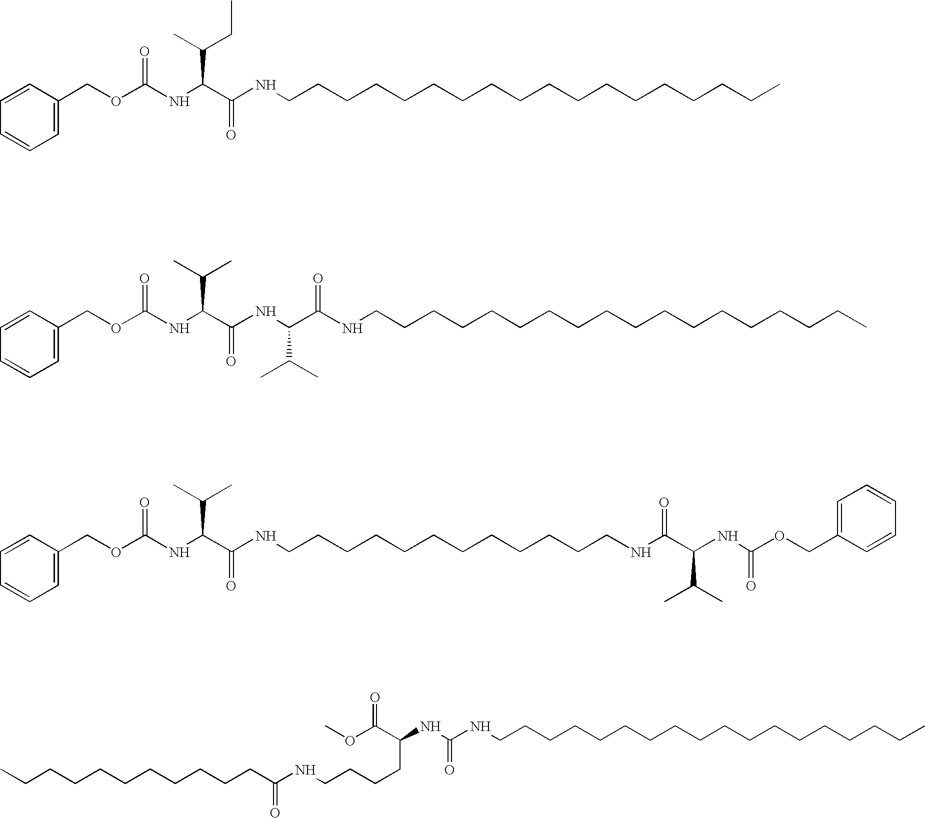

In the illustrative embodiment, the solar cell may also include an electrically insulating layer that is disposed over at least a portion of an electron conductor layer to prevent or substantially prevent electrical contact between the electron conductor layer and the hole conductor layer and/or prevent or reduce electron/hole recombination at the interface. The insulating layer may be formed of any suitable material, using any suitable process or technique process. In some instances, the insulating layer may be deposited and/or sputtered onto at least a portion of an electron conductor layer. In some cases, an insulating layer may be formed simply by submerging the electron conductor layer into appropriate precursor solution(s), followed by a sintering process.

In some instances, the insulating layer may be formed of a material that has a relatively large band gap and/or a relatively high melting point. Illustrative but non-limiting examples of suitable insulating materials include, but are not limited to, oxide-based materials such as SiO₂, Al₂O₃, AlN, ZrO₂, Ga₂O₃, La₂O₃, Nd₂O₃, or Yb₂O₃. Another example of a suitable insulating material includes, but is not limited to, Si₃N₄.

In some cases, the insulating layer may include pores that are configured to accommodate absorber materials such as photo-reactive dyes and/or quantum dots. The pores may be formed within the insulating layer using any suitable process or technique. In some cases, pores may be formed within the insulating layer using electro perforation, stamping, embossing, physical and/or chemical etching using, for example an appropriate nano-material template as a mask, and/or using any other suitable technique or process. In some instances, pores may be formed by first attaching a sacrificial nanowire/nanotube template or array to the electron conductor layer, followed by deposition of the insulating material between the nanowire/nanotube materials of the nanowire/nanotube template or array. The nanowire/nanotube template or array may then be selectively removed, leaving pores formed within the insulating material.

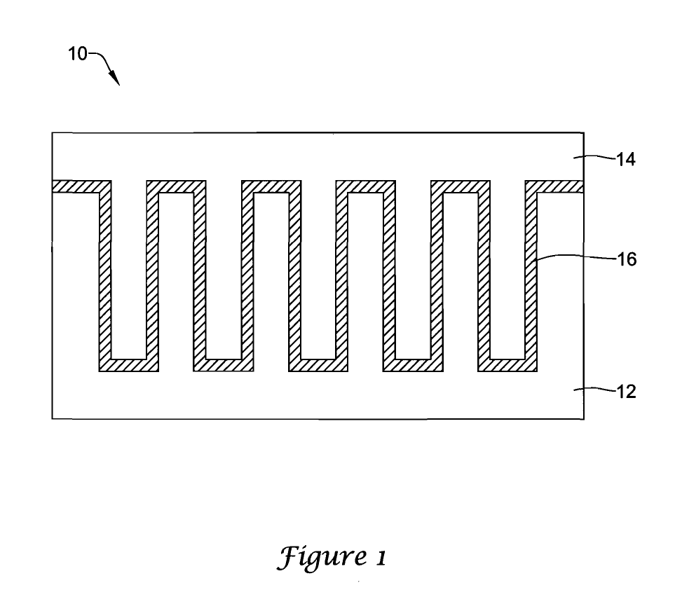

Turning now to the Figures, FIG. 1 is a schematic view of an illustrative solar cell 10. The illustrative solar cell 10 includes an electron conductor layer 12 and a hole conductor layer 14. Electron conductor layer 12 may be formed of any suitable conductive material that can accept injected electrons. In some instances, electron conductor layer 12 may be or include an n-type conductive material. In some cases, electron conductor layer 12 may include or otherwise be formed of sinterized titanium dioxide, but this is not required. Hole conductor layer 14 may be formed of any suitable material that can accept holes (i.e., donate electrons). In some instances, hole conductor layer 14 may be or include a p-type conductive material, but this is not required.

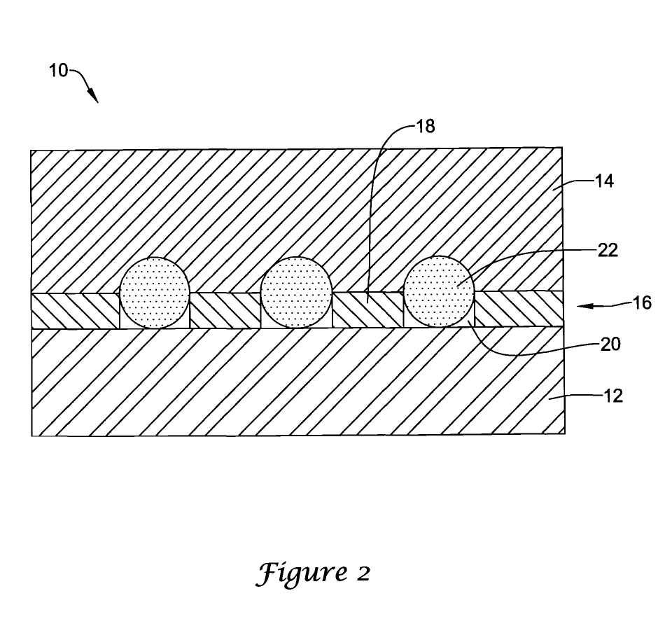

As better shown in FIG. 2, the illustrative solar cell 10 may also include an intermediate layer 16. FIG. 2 is an enlarged schematic cross-sectional view of a portion of the illustrative solar cell 10 of FIG. 1. With reference to FIG. 2, intermediate layer 16 may be seen as including an insulating layer 18 that includes a number of pores 20. Insulating layer 18 may be formed of any suitable material(s) using any suitable process or technique. In some cases, insulating layer 18 may be formed of a material that has a relatively high band gap, thereby helping to prevent or substantially reduce movement of electrons through the insulating layer 18. By preventing or reducing electron movement through insulating layer 18, the efficiency of solar cell 10 may be increased because, for example, electron/hole recombination at the interface may be reduced or eliminated. In the illustrative embodiment, insulating layer 18 may include a plurality of pores 20 that can be formed in any suitable manner, and may be configured to accommodate absorber materials.

In some cases, pores 20 may be formed within the insulating layer using electro perforation, stamping, embossing, physical and/or chemical etching using, for example an appropriate nano-material template as a mask, and/or using any other suitable technique or process. In some instances, pores may be formed by first attaching a sacrificial nanowire/nanotube template or array to the electron conductor layer, followed by deposition of the insulating material between the nanowire/nanotube materials of the nanowire/nanotube template or array. The nanowire/nanotube materials may then be selectively removed, leaving pores formed within the insulating material.

Absorber materials 22, which may include photo-reactive dyes, quantum dots or any other suitable absorber material(s), may be disposed within pores 20. It will be appreciated that in some instances, absorber materials 22 may be in direct physical and/or electrical contact with electron conductor layer 12. Also, absorber materials 22 may be in direct physical and/or electrical contact with hole conductor layer 14, as shown. When so provided, the rate at which electrons can move (in response to incident photons) from absorber material 22 to electron conductor layer 12 and/or from hole conductor layer 14 to absorber material 22 is faster than if the electrons had to pass through an intervening layer.

In some cases, the absorber material may include a plurality of absorbers each disposed within a corresponding pore, as shown in FIG. 2. Also, and in some cases, the plurality of absorbers may each having a dimension in a direction perpendicular to the primary plane (i.e. horizontal plane in FIG. 2) of the insulating layer 16 that is greater than an average thickness of the insulating layer 16, as shown in FIG. 2.

It will be appreciated that one or more of electron conductor layer 12 and/or hole conductor layer 14 may be transparent or at least substantially transparent to incident light within a particular wavelength or range of wavelengths so that incident photons can reach absorber material 22. Once an incident photon (or photons) is/are absorbed by absorber material 22, absorber material 22 may eject one or more electrons into electron conductor layer 12. Absorber material 22 may then be reduced by one or more electrons that are provided by hole conductor layer 14. It will be recognized that solar cell 10 may include one or more additional layers not shown, such as conductive layers in contact with electron conductor layer 12 and hole conductor layer 14, sometimes to form back electrodes (not explicitly shown) of the solar cell 10. Other layers such as protective layers may also be included.

The disclosure should not be considered limited to the particular examples described above, but rather should be understood to cover all aspects of the invention as set out in the attached claims. Various modifications, equivalent processes, as well as numerous structures to which the invention can be applicable will be readily apparent to those of skill in the art upon review of the instant specification.

We claim:

1. A solar cell comprising:
an electron conductor layer;
a hole conductor layer;
an insulating layer disposed between the electron conductor layer and the hole conductor layer, the insulating layer having a plurality of pores; and
absorber material disposed at least partially within at least some of the plurality of pores.

2. The solar cell of claim 1, wherein the absorber material includes a plurality of absorbers each disposed within a corresponding pore such that at least some of the plurality of absorbers are in physical contact, electrical contact, or both with the electron conductor layer.

3. The solar cell of claim 1, wherein the absorber material includes a plurality of absorbers each disposed within a corresponding pore such that at least some of the plurality of absorbers are in physical contact, electrical contact, or both with the hole conductor layer.

4. The solar cell of claim 1, wherein the absorber material includes a plurality of absorbers each disposed within a corresponding pore such that at least some of the plurality of absorbers are in physical and electrical contact with the electron conductor layer and the hole conductor layer.

5. The solar cell of claim 1, wherein the absorber material includes a plurality of absorbers each having a dimension in a direction perpendicular to the insulating layer that is greater than an average thickness of the insulating layer.

6. The solar cell of claim 1, wherein the hole conductor layer comprises a conductive polymer.

7. The solar cell of claim 1, wherein the hole conductor layer comprises a non-polymeric molecule.

8. The solar cell of claim 1, wherein the hole conductor layer comprises an electrolyte solution.

9. The solar cell of claim 8, wherein the electrolyte solution further comprises one or more of the following gelator molecules:

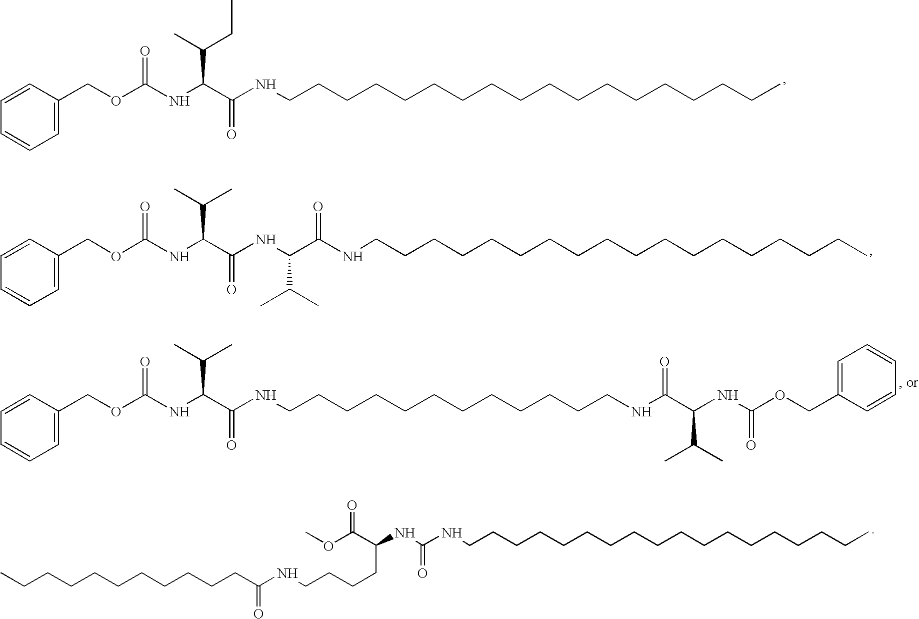

10. The solar cell of claim 1, wherein the electron conductor layer comprises titanium dioxide.

11. The solar cell of claim 1, wherein the insulating layer comprises one or more of SiO₂, Si₃N₄, Al₂O₃, AlN, ZrO₂, Ga₂O₃, La₂O₃, Nd₂O₃, and Yb₂O₃.

12. The solar cell of claim 1, wherein the absorber material comprises light sensitive dye molecules.

13. The solar cell of claim 1, wherein the absorber material comprises quantum dots.

14. A solar cell comprising:
an electron conductor layer comprising sinterized titanium dioxide;
an insulating layer disposed over the electron conductor layer, the insulating layer having a plurality of pores;
a plurality of quantum dots, at least some of the plurality of quantum dots being disposed at least partially within at least some of the plurality of pores of the insulating layer; and
a hole conductor layer disposed over the insulating layer and the plurality of quantum dots, the hole conductor layer comprising a conductive polymer.

15. The solar cell of claim 14, wherein the insulating layer comprises an oxide-based insulating layer.

16. The solar cell of claim 14, wherein at least some of the plurality of quantum dots are in electrical and physical contact with the electron conductor layer and the hole conductor layer.

17. The solar cell of claim 14, wherein at least some of the plurality of quantum dots have a dimension in a direction perpendicular to the insulating layer that is greater than an average thickness of the insulating layer.

18. A method of forming a solar cell, the method comprising the steps of:
providing an electron conductor layer;
disposing an insulating layer over the electron conductor layer;
processing the insulating layer to include pores configured to accommodate absorber material;
providing the absorber material at least partially within the pores formed in the insulating layer; and
disposing a hole conductor layer over the absorber materials and the insulating layer.

19. The method of claim 18, wherein processing the insulating layer comprises electro perforation or an etching process.

20. The method of claim 18, wherein disposing and processing the insulating layer comprises providing a sacrificial nano-material template, followed by depositing the insulating layer and subsequently removing the nano-material template.
